(19) United States
(12) Patent Application Publication
(10) Pub. No.: US 2018/0168025 A1
(43) Pub. Date: Jun. 14, 2018

(54) Electronic device comprising a printed circuit board with improved cooling

(71) Applicants: IFP Energies nouvelles, Rueil-Malmaison (FR); Mavel S.r.l., PONT SAINT MARTIN (IT)

(72) Inventors: Wissam DIB, SURESNES (FR); Abdenour ABDELLI, BOUGIVAL (FR); Fabien VIDAL-NAQUET, PARIS (FR); Marco FRANCESSETTI, BORGARO TORINESE (IT); Denny CHIONO, SAINT NICOLAS (IT); Davide BETTONI, SETTIMO VITTONE (IT)

(21) Appl. No.: 15/577,694

(22) PCT Filed: May 30, 2016
(86) PCT No.: PCT/EP2016/060693

§ 371 Date: Nov. 28, 2017

(30) Foreign Application Priority Data
May 28, 2015 (FR) 1554836

(51) Int. Cl. H05K 1/02

(52) U.S. Cl. CPC H05K 1/0206; H05K 1/0209; H05K 2201/0959; H05K 2201/066; H05K 1/0298

(57) ABSTRACT

The present invention is an electronic device (10) comprising a printed circuit board (12) bearing at least one component comprising at least one of a power component (14) and at least one power conductor (18). The printed circuit board comprises an alternating succession of insulating (22) and conductive (24) layers, wells (30, 30′) bearing an internal electrically and thermally conductive coating (32) which passes through the thickness of the board, and a cooling device (34) for the board. The interior of the wells are filled with a thermally conductive material (44) to produce a thermal bridge between the component and the cooling device (34).

### CROSS REFERENCE TO RELATED APPLICATIONS

Reference is made to International Application No. PCT/EP2016/060693 filed May 30, 2016, and French Application No. 15/54.836 filed May 28, 2015, which are incorporated herein by reference in their entirety.

### BACKGROUND OF THE INVENTION

### Field of the Invention

The present invention relates to an electronic device comprising a printed circuit board with enhanced cooling of the components that it bears.

### Description of the Prior Art

An example of a printed circuit board is an inverter which converts a direct current, generally supplied by a battery, into an alternating current, generally to be supplied to an electric machine, like a motor.

To perform this operation, the inverter typically comprises various components with a set of power components, which perform the alternation of direct current/alternating current conversion, and a set of signal components, which process measurements and provide control logic for the power components.

These components are typically mounted on a printed circuit board, which provides the capability of an electrical link and which acts as a mechanical support for these components.

However, such a printed circuit board is inefficient from a thermal aspect, and is inappropriate for discharging the heat generated by the power components.

To ensure the cooling of such a board, as is better described in the patent application EP 2 809 135, the latter has a succession of alternating electrically conductive and insulating layers, with at least one component mounted on the top layer and a cooling device for the components of the board.

In the example described by this patent application, this cooling device is a heat sink with fins which is placed on the bottom layer of the board.

To ensure the transmission of the heat between the components and the heat sink, the board is passed right through by wells coated internally with a layer of thermally conductive metal.

These wells advantageously link the electronic components to the heat sink and make it possible to discharge the heat generated by these components to the heat sink, thus ensuring the cooling of the board.

This device is advantageous because it makes it possible to discharge some of the heat. However it may prove inadequate when large quantities of heat are to be dissipated.

### SUMMARY OF THE INVENTION

The present invention provides a remedy to the above drawbacks by virtue of an electronic device which ensures the cooling of these components even when they give off a large quantity of heat.

Furthermore, the device of the invention uses substantially the same techniques as those which are currently employed for the fabrication of printed circuit boards and for mounting components on the printed circuit board.

The present invention relates to an electronic device comprising a printed circuit board bearing at least one component comprising at least one power component and/or at least one power conductor. The printed circuit board comprises an alternating succession of insulating and conductive layers, at least one well bearing an internal electrically and thermally conductive coating and passing through the thickness of the board, and a cooling device for the board. The interior of at least one well is also filled with a thermally conductive material to produce a thermal bridge between the component and the cooling device.

The thermally conductive material can be the material linking the component with the board.

The thermally conductive material can be tin.

The board can bear a thermal paste placed between the bottom layer of the board and the cooling device.

The wells can be obtained by drilling and can be coated internally with a layer of conductive metal and be filled with a thermally conductive material.

The wells can be obtained by drilling, can be coated internally with a layer of conductive metal and be filled with a thermally conductive material as well as a thermal paste.

### BRIEF DESCRIPTION OF THE DRAWINGS

The other features and advantages of the invention will now become apparent on reading the following description, given in a purely illustrative and nonlimiting manner, and to which are attached:

FIG. 1 is a local schematic plan view of the printed circuit board; and

FIG. 2 is a schematic view in cross section along the line 2-2 of FIG. 1.

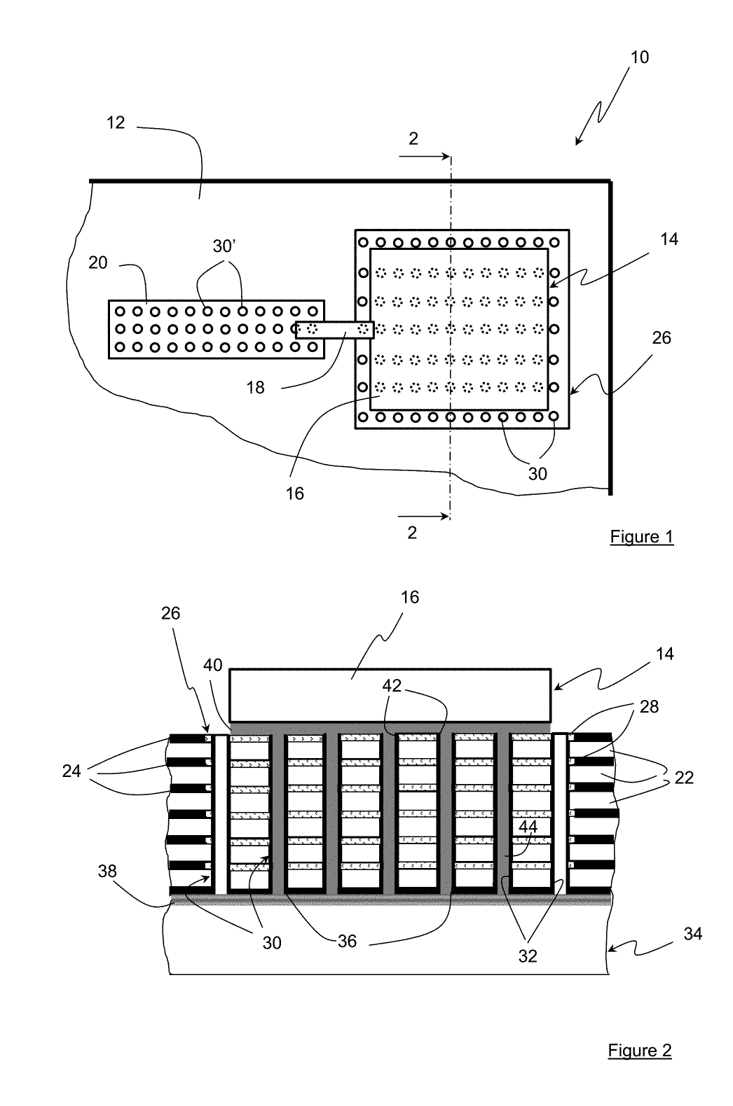

FIG. 1 shows a part of an electronic device 10 comprising a printed circuit board 12, which here is a part of a device comprising switching circuits, for example an inverter.

The printed circuit board 12 bears at least one series of components with a power component 14 and its main body 16 and at least one power conductor 18 which is capable of receiving or transmitting electrical power by being advantageously linked to a conductive track 20.

As a nonlimiting example, the power component 14 can be an electronic component, such as, for example, a solid-state switch, a MOSFET (metal-oxide-semiconductor field-effect transistor), an IGBT (insulated gate bipolar transistor), a resistor, etc.

Similarly, the component can be a component which is not considered to be a power component but nevertheless is a component which generates a significant heat, like a processor.

In FIG. 2, the printed circuit board 12 preferably comprises a succession of insulating layers 22 and conductive layers 24 which mutually alternate by being stacked one on top of the other.

These layers are linked to one another by any known mechanism available to those skilled in the art.

The insulating layers 22 preferably comprise an electrically and thermally insulating material, for example glass fibers. The conductive layers 24 advantageously comprise a mixture of electrically and thermally conductive material, preferably a metal such as, for example, copper, and an electrically and thermally insulating material.

The board 12 further comprises a mounting base 26 for receiving the main body 16 of the power component.

This mounting base 26 comprises a conductive plate 28 for each conductive layer 24 and in contact therewith. These plates advantageously all have the same form and are preferably stacked.

The board comprises, level with the mounting base 26, a plurality of wells 30 substantially at right angles to the face of the layers 22 and 24 which pass through the thickness of the printed circuit board and are evenly spaced apart from one another.

These wells make it possible to produce an electrical and thermal contact with the conductive plates 28 of the conductive layers 24.

For that, these wells comprise an internal coating of conductive metal 32, preferably the same metal as the conductive layers, such as copper.

These wells are preferably obtained by drilling through the thickness of the printed circuit board. These drill-holes are then coated internally with a thin layer of conductive metal, for example by a galvanization method, leaving a hollow column remaining inside this well.

A cooling device 34 for the board is also borne by this board. Preferentially, this device is placed on the bottom layer of the board to discharge heat generated by the components of the board with the external medium, which here is air.

Advantageously, this device is a heat sink with fins 34 which is in contact with the bottom ends 36 of the wells 30 through a hardenable material 38, like a thermal paste. This paste, which is malleable, is placed between the bottom layer of the board and the wall of the heat sink which faces it by being in contact with the internal conductive coating of the wells. After it has been placed, the paste hardens and then ensures a rigid link between the board and the heat sink as well as the thermal connection with the wells.

As can be seen in FIG. 2, the body 16 of the power component 14 is advantageously connected to the mounting base 26 through a link layer 40 of a known material like tin.

In addition to producing the connection with the base, this material, which is also thermally conductive, makes it possible to produce the thermal connection with the top ends 42 of the wells and with the internal coating of the wells 30.

As is better illustrated in FIG. 2, the hollow column inside the wells is filled with a heat conductive material 44 between the two ends 36 and 42. Preferentially, this material comes from the material of the link layer which here is tin. Thus, during the connection operation, the tin flows into the hollow column of the well until the hollow column between the two ends of the well is completely filled.

This makes it possible to produce both the connection of the component 14 with the base and the filling of the interior of the wells.

A thermal bridge is therefore created between the component 14 and the cooling heat sink 34 through the materials (copper and tin) inside the wells 30 and the thermal paste 38.

By virtue of that, the thermal conductivity of the board is greater by approximately 50% than that of the boards of the prior art.

It should be noted that the use of a thermal paste makes possible ensuring of the thermal contact between the tin and the heat sink when the tin does not reach the bottom end of one or more wells. In effect, after the operation of filling of the wells and during the placement of the thermal paste, which is initially malleable, the latter penetrates into the wells until it is in contact with the tin. This contact then makes it possible to ensure the transfer of heat between the wells and the heat sink.

Obviously, and without departing from the scope of the invention, the conductive track 20 of FIG. 1 is linked to the heat sink by a multiplicity of wells 30′ provided with an internal copper-based coating. In the junction zone with the power conductor 18, the interior of these wells is filled with a heat conductive material. This material is advantageously tin which is used to ensure the link between the conductor and the track.

Preferentially, the wells 30′ facing the track 20 are filled with heat conductive material, here tin, so as to ensure the thermal conduction, to the cooling device 34, of the heat produced by Joule effect by the track.

1-26. (canceled)

27. An electronic device comprising:
a printed circuit board bearing at least one component comprising at least one power component and at least one power conductor, the printed circuit board including an alternating succession of insulating and conductive layers, wells bearing an internal electrically and thermally conductive coating and passing through a thickness of the board, and a cooling device for the board, and wherein an interior of the wells is also filled with a thermally conductive material which provides a thermal bridge between at least one component and the cooling device.

28. An electronic device according to claim 27, wherein the thermally conductive material is the material linking the component with the board.

29. An electronic device according to claim 27, wherein the thermally conductive material is tin.

30. An electronic device according to claim 28, wherein the thermally conductive material is tin.

31. An electronic device according to claim 27, wherein the board bears a thermal paste placed between a bottom layer of the board and the cooling device.

32. An electronic device according to claim 27, wherein the wells are drilled holes coated internally with a layer of conductive metal and filled with a thermally conductive material.

33. An electronic device according to claim 28, wherein the wells are drilled holes coated internally with a layer of conductive metal and filled with a thermally conductive material.

34. An electronic device according to claim 29, wherein the wells are holes coated internally with a layer of conductive metal and filled with a thermally conductive material.

35. An electronic device according to claim 30, wherein the wells are holes coated internally with a layer of conductive metal and filled with a thermally conductive material.

36. An electronic device according to claim 31, wherein the wells are holes coated internally with a layer of conductive metal and filled with a thermally conductive material.

37. An electronic device according to claim 28, wherein the wells are holes which are coated internally with a layer of conductive metal and filled with a thermally conductive material and a thermal paste.

38. An electronic device according to claim 29, wherein the wells are holes which are coated internally with a layer of conductive metal and filled with a thermally conductive material and a thermal paste.

39. An electronic device according to claim 30, wherein the wells are holes which are coated internally with a layer of conductive metal and filled with a thermally conductive material and a thermal paste.

40. An electronic device according to claim 31, wherein the wells are holes which are coated internally with a layer of conductive metal and filled with a thermally conductive material and a thermal paste.

41. An electronic device according to claim 32, wherein the wells are holes which are coated internally with a layer of conductive metal and filled with a thermally conductive material and a thermal paste.
